(19) United States
(12) Patent Application Publication
(10) Pub. No.: US 2009/0114281 A1
(43) Pub. Date: May 7, 2009

(54) ABSORBER FOR THE CONVERSION OF SOLAR RAYS INTO THERMAL ENERGY

(76) Inventor: Gerald Gobel, Wien (AT)

Correspondence Address: Pequignot + Myers LLC, 140 Marine View Avenue, Solana Beach, CA, 92075, US

(21) Appl. No.: 12/094,923

(22) PCT Filed: Nov. 23, 2006
(86) PCT No.: PCT/EP2006/011251

§ 371 Date: May 23, 2008

(30) Foreign Application Priority Data
Nov. 23, 2005 (DE) 10 2005 055 858.5

(51) Int. Cl. H01L 31/00

(52) U.S. Cl. 136/259

(57) ABSTRACT

An absorber for converting solar rays into thermal energy, in particular for use in a solar collector (10), is proposed, which comprises a non-porous dark ceramic, wherein the absorber is flowed through by a heat transport medium.

The invention relates to an absorber for converting solar rays into thermal energy, in particular for use in a solar collector, which is flowed through by a heat transport medium.

Solar collectors are used to convert solar energy into thermal energy and as such to make it useable. They essentially comprise an absorber, which is made of a material with good thermal conductivity, such as, e.g., copper or steel, and a piping system through which a liquid or a gas transports the absorbed energy from the absorber to a site of application of the thermal energy obtained. To increase the operating temperature of a solar collector, in addition optical equipment such as, e.g., heliostats or parabolic troughs, can be used in order to focus the solar rays on the absorber.

Absorbers usually have a black surface, which is obtained through the application of a black pigmented paint in order to ensure a maximum absorptive capacity of solar energy. However, the disadvantage hereby is that whenever the absorber is used in a solar collector with corresponding capacity, such as, e.g., a solar thermal power plant, in which large-area optical systems are used to concentrate the incident sunlight on the absorber in order to achieve high absorber temperatures, this can lead to a destruction of the absorber coating or paintwork. In order for this coating or paintwork and its coloring not to be destroyed too quickly, the absorbers for their part are therefore kept in evacuated glass tubes in order to prevent oxygen access, which, however, on the one hand increases costs and on the other hand requires a regular cleaning of the evacuated glass tubes, since otherwise they themselves could be heated and thereby destroyed, which, however, could necessitate the corresponding plant being switched off.

In contrast, it is the object of the invention to provide an absorber, flowed through by a heat transport medium, for converting solar rays into thermal energy, in particular for use in a solar collector, which also permits a cost-effective and largely maintenance-free application when used in high-capacity solar collectors.

This object is attained according to the invention in that the absorber essentially comprises a non-porous ceramic of dark material. The central concept of the invention lies namely, instead of using metal pipes with a dark in particular black paint or coating, in using non-porous ceramic pipes that innately comprise a dark material, which on the one hand has the advantage that the absorber does not need to be specially blackened, and on the other hand eliminates the necessity of preventing oxygen access through encapsulation in vacuum tubes. The use of ceramics means there is also a possibility of permitting absorber temperatures up to much higher than 400° C., in particular up to 800° C. or even higher, depending on the optical equipment used.

According to the invention it is thereby proposed for the non-porous or impervious ceramic to be a non-oxide ceramic on the basis of silicon carbide (SiC), in particular technical silicon carbide, which among other things has a high thermal conductivity and a low thermal expansion and furthermore can also be used at very high temperatures. Technical silicon carbide is dark colored (black to green) due to impurity present, the degree of coloration decreasing with increasing degree of purity of the silicon carbide.

Above all pressureless sintered silicon carbide (SSIC) and reaction-bonded silicon infiltrated silicon carbide (SISIC) have proven to be particularly suitable non-oxide ceramics on the basis of silicon carbide, although liquid-phase sintered silicon carbide (LPSIC), hot-pressed silicon carbide (HPSiC) and hot isostatically pressed silicon carbide (HIPSIC) can also be used.

Pressureless sintered silicon carbide (SSIC) is produced from ground finest SIC powder that is processed with sinter additives in the customary ceramic forming variants and sintered at 2000 to 2200° C. under inert gas. SSIC is characterized by a high strength that remains virtually constant up to high temperatures of approx. 1600° C. This material furthermore has a high thermal shock resistance, high thermal conductivity, high abrasion resistance and a diamond-like hardness.

In contrast, reaction-bonded silicon infiltrated silicon carbide (SISIC) is composed to approx. 85 to 94% of SIC and accordingly of 15 to 6% metallic silicon. Furthermore, SISIC has virtually no residual porosity. This is achieved in that a molded article of silicon carbide and carbon is infiltrated with metallic silicon. The reaction between liquid silicon and the carbon leads to a SIC bonding matrix, wherein the residual pore space is filled with metallic silicon. The advantage of this production method is that, in contrast to the powder sintering techniques, during the siliconization process the components do not undergo any shrinkage. Therefore extraordinarily large or long absorbers can be produced with precise dimensions. Although the range of use of SISIC is limited to approx. 1380° C. because of the melting point of the metallic silicon, up to this temperature range SISIC has a high strength and corrosion resistance connected with good thermal shock resistance and abrasion resistance.

In summary, silicon carbides are thus characterized by properties such as high hardness, corrosion resistance even at high temperatures, high abrasion resistance, high strength even at high temperatures, oxidation resistance up to very high application temperatures, good thermal shock resistance, low thermal expansion and very high thermal conductivity. In particular the low thermal expansion is particularly advantageous if the absorber is embodied in a tubular manner or, as provided in one embodiment of the invention, is composed of a plurality of tubular elements densely connected to one another. Absorbers of this type are used in particular in solar power plants that use parabolic trough collectors that comprise curved mirrors that concentrate the sunlight on an absorber tube running in the focal line, which tube is fixed by holders in the focal line of the collector. The lengths of such collectors and thus also the length of the absorber tubes used can be between 20 and 150 meters depending on the type, wherein the individual tubular elements connected to one another usually have a length of approx. 2 to 4 meters. Furthermore, the aforementioned properties of silicon carbide make it possible to largely do without the measures provided in the prior art to absorb the length expansion, to support the weight and to prevent the deformation at high temperatures of the absorber materials used.

In order to render possible a simple connection of a plurality of absorbers embodied in a tubular manner to form a single absorber element, according to the invention it can be provided for the connection of two tubular elements to be carried out by a slip joint. This type of connection permits a quick assembly, but has the disadvantage that it is sensitive to longitudinal forces, which, however, occur only to a slight extent through the use according to the invention of non-oxide ceramics with a low thermal expansion.

However, it is also conceivable to use flange joints or screw joints to connect two tubular elements.

However, in addition it can also be provided for metal clamps to be used to secure a slip joint, which prevent longitudinal forces occurring in the absorber from loosening the slip joints.

Due to the properties of silicon carbide, e.g., reaction-bonded silicon infiltrated silicon carbide (SISIC), which does not undergo any shrinkage during the production process, the individual tube segments can be produced very precisely, which would even make it possible to connect the individual tubular elements to one another with positional accuracy and tightly without additional sealing. However, it can also be provided according to the invention for the sealing of the slip joints to be carried out by means of a silicon seal that is adapted to the tubular form of the tubular elements, or for the seal of the slip joint to be carried out by means of a refractory putty or adhesive.

Liquid or gaseous heat transfer fluids, such as water, liquid sodium, isobutane, thermal oil or superheated water vapor, etc., can be used as a heat transport medium. If thermal oil is used as a heat transport medium, temperatures of up to 390° C. can be reached, which are used in a heat exchanger to generate steam and then fed to a conventional steam turbine. Superheated water vapor, however, is used with direct steam generation, which does not need a heat exchanger, since the heated water vapor is generated directly in the absorber tubes and fed to a steam turbine, which renders possible temperatures of above 500° C., when parabolic trough collectors are used. If furthermore the absorber according to the invention is used with solar power plants in which the solar radiation) is concentrated on a central absorber with the aid of hundreds to thousands of automatically positioned mirrors (heliostats), maximum temperatures of approx. 1300° C. are possible.

According to the invention it can also be provided for the heat transport medium to comprise silicon oil, which is characterized by a low volatility, low temperature coefficients of viscosity, fireproofness and high resistance with respect to acids and lyes, but also has a high electrical resistance and a low surface tension. In addition, silicon oil is neutral in terms of odor and taste and physiologically indifferent. Through the use of the absorber according to the invention with a heat transport medium based on silicon oil, temperatures up to far higher than 400° C., in particular up to 800° C., sometimes even higher, can be realized.

Exemplary embodiments of the invention are described in more detail below with reference to the figures. They show:

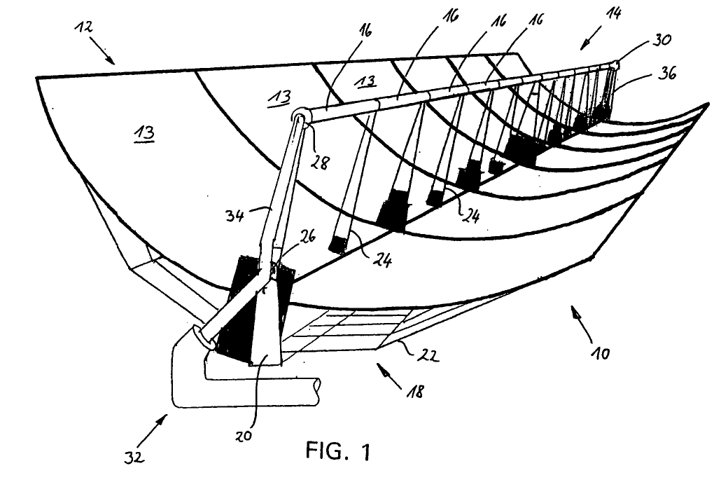

FIG. 1A perspective representation of a parabolic trough collector that contains the absorber according to the invention;

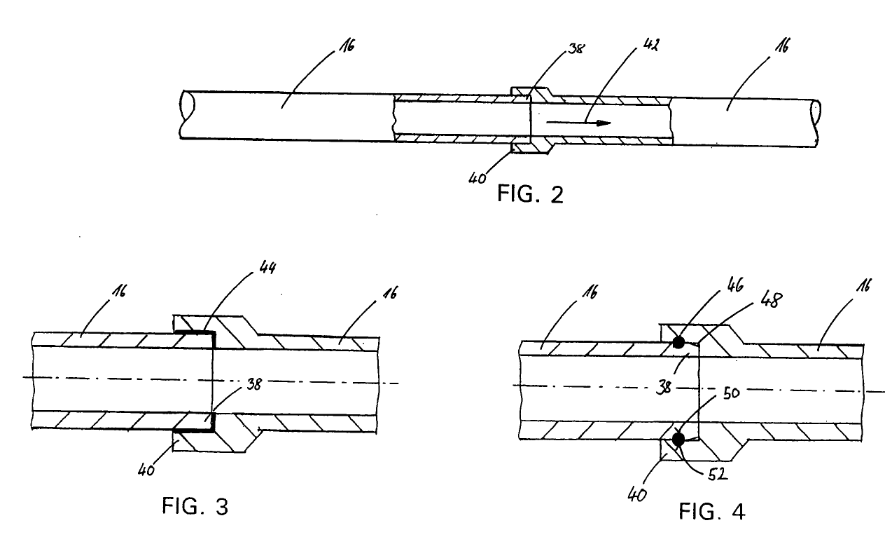

FIG. 2 A cross section through the joint of two tubular absorbers connected to one another by a slip joint;

FIG. 3 An enlarged view of the slip joint shown in FIG. 2;

FIG. 4 An enlarged view of a slip joint according to another embodiment of the invention similar to FIG. 3; and

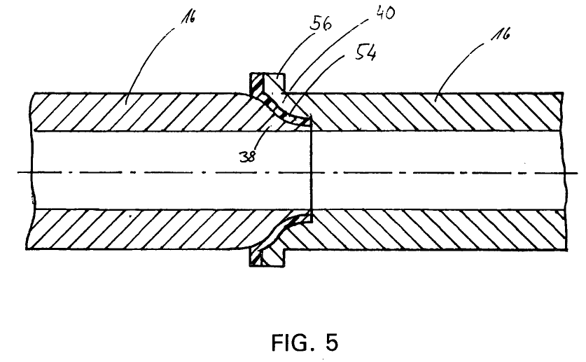

FIG. 5 An enlarged view of a slip joint according to another embodiment of the invention.

FIG. 1 shows a perspective representation of a parabolic trough converter 10. The parabolic trough converter 10 has an extended reflector 12 that as a rule is made of glass that is coated with silver and thus acts as a mirror. In cross section the reflector 12 has the shape of a parabola, and in the focal line (not shown) of the reflector 12 an extended absorber 14 is located comprising a plurality of individual absorber tube elements 16, in which absorber a heat transport medium circulates, such as, e.g., silicon oil, thermal oil or water vapor. The heat carrier and the structure of the absorber tube 14 are not shown in FIG. 1

The reflector 12 assembled from a plurality of reflector elements 13 has a support structure 18, which essentially comprises a plurality of carriers 20 attached to the base and a framework structure 22, which is used both to support the individual reflector elements 13 free in a manner from deformation and to bear support elements 24 with which the absorber tube 14 is held always in the focal line of the reflector 12. In order to make it possible for the reflector 12 to track the sun, furthermore rotary drives (not shown) are provided, which permit a swivel motion of the framework structure 22 with respect to the carriers 20 on rocker pivots 26, one of which is shown.

On the opposite ends 28 and 30 of the absorber 14, the absorber is connected to a line system 32 that has an inlet 34, through which the heat transport medium is introduced into the absorber 14, and an outlet 36 through which the heat transport medium is discharged. Depending on the heat transport medium used, it is furthermore possible to guide the heat transport medium either first to a heat exchanger (not shown) for steam generation, which is then fed to a conventional steam turbine, or if the superheated water vapor is generated directly in the absorber tubes, to feed it directly to a steam turbine without interposition of a heat exchanger.

FIG. 2 is a cross section through a connection of two absorber tube elements 16, 16, which in the present embodiment are together part of the absorber 14. Each absorber tube element 16 comprises a non-porous/impervious non-oxide ceramic on the basis of silicon carbide, which is present in technical form and is dark. The silicon carbide used has a very high hardness, corrosion resistance even at high temperatures, high abrasion resistance, high strength even at high temperatures, oxidation resistance up to high application temperatures, good thermal shock resistance, low thermal expansion, very high thermal conductivity and good tribological properties.

Preferably pressureless sintered silicon carbide (SSIC) and reaction-bonded silicon infiltrated silicon carbide (SISIC) are used, which due to its production process renders possible components that do not undergo any shrinkage during the siliconization process, through which extraordinarily large components can be produced with precise dimensions. Since furthermore silicon carbide has only a low thermal expansion, very long absorbers 14 with correspondingly numerous individual absorber tube elements 16 can be used, without extensive consideration having to be given to the axial extension of the absorber tube 14.

However, alternatively, liquid-phase sintered silicon carbide (LPSIC) or hot-pressed silicon carbide (HPSIC) and hot isostatically pressed silicon carbide (HIPSIC) can be used, which also belong to the group of the impervious or non-porous silicon carbides.

The technical silicon carbide used has a dark color (light green/dark green, black, gray) due to impurities present, depending on the degree of purity, so that it is not necessary to blacken the tubes specially, which means it is not necessary either to prevent the oxygen access by encapsulation in vacuum tubes in order to prevent a too rapid destruction of the absorber coating or coloring, as is necessary with the prior art.

As shown in FIG. 2, the two absorber tube elements 16, 16 are connected by a slip joint, with which a tip end 38 of an absorber tube element 16 is inserted into the bell 40 of an adjacent absorber tube element 16, which permits a quick assembly. The flow direction of the heat transport medium is shown in FIG. 2 by an arrow 42 and runs from the bell of a tube element to its tip end. Furthermore, the slip joint can additionally be secured via retaining clips or retaining screws (not shown) in order to prevent a loosening of the slip joint.

FIG. 3 shows an enlarged representation of the slip joint of FIG. 2, which shows that the slip joint in addition is sealed by an assembly adhesive or water-glass adhesive 44 that does not contain any organic solvents, is not combustible and can be used in temperature ranges up to much higher than 1000° C. Alternatively, however, other refractory adhesives or luting agents which have temperature resistances of up to 1700° C. or ceramic adhesive substances can be used, which have temperature resistances up to 1700° C., or ceramic adhesive substances are used that are inserted in liquid form in the connection region of the two absorber tube elements and after the hardening connects the absorber tube elements 16 reliably.

FIG. 4 shows an alternative embodiment of the invention in which two absorber tube elements 16, 16, as in FIG. 3, are connected to one another via a slip joint, in which one tip end 38 of the one absorber tube element 16 is inserted into the bell of the other absorber tube element 16. In addition, however, with this embodiment a silicon seal 46 is provided in order to seal the slip joint. In the embodiment shown in FIG. 4, the tip end 38 of the one absorber tube element 16 is provided with a phase 48 in order on the one hand to facilitate the introduction of the tip end 38 into the bell 40 of the other absorber tube element 16, as well as to serve as a leading aid for the silicon seal 46 in order not to jam the same during insertion of the tip end 38 into the bell 40. With the embodiment shown, both the tip end 38 as well as the bell 40 has a respective groove or recess 50 or 52 to accommodate the silicon seal 46 (which in FIG. 4 is shown as an O ring) in order in this manner to render possible an additional fixing of the two absorber tube elements 16, 16 connected to one another.

FIG. 5 shows another embodiment of the invention in which two absorber tube elements 16, 16 as in FIG. 4 are connected to one another via a slip joint, in which a tip end 38 of the one absorber tube element 16 is inserted into the bell 40 of the other absorber tube element 16, wherein the slip joint is sealed via a silicon seal 54. However, this embodiment differs from the embodiment shown in FIG. 4 in that the tip end 38 is not chamfered, as shown in FIG. 4, but is embodied with a bottle-neck shaped tapering tip end 38 and a trumpet-shaped bell 40 embodied in a correspondingly opposite manner. Furthermore, with this embodiment the elastomer bell seal (silicon seal) 54 is not inserted into a groove or recess, but lies flat between the tip end 38 and the bell 40 in order to seal the connection area.

With the assembly of the elastomer bell seal 54, this is placed “dry” on the tip end 38 of the one (left) absorber tube element 16, then covered on the outside with a lubricant, likewise the inside of the bell 40 of the other (right) absorber tube element 16. Now the (left) absorber tube element 16 with the seal attached is placed on the bell 40 of the other (right) absorber tube element 16 and together with the bell seal 54 pressed into the bell 40, wherein the tip end 38 centers itself in the bell 40 through the conical form of the bell seal 54.

The bottle-neck shaped form of the tip end 38 shown in FIG. 5 is selected only by way of example and can be embodied in a different manner depending on the bell seal used, e.g., with a longer or shorter neck, with different material thickness, etc. Furthermore this type of slip joint additionally can be secured via a retaining clip or retaining screw in order to prevent a loosening of the slip joint.

However, furthermore it is also possible, instead of the bell 40 which is attached to one end of a respective absorber tube element 16, to embody these ends as tip ends and to provide separate bells that are pushed over the two tube elements to be connected. However, alternatively it is also possible to use other types of connection, such as, e.g., flange connections or screw connections, depending on the material properties of the silicon carbide used in order in this manner to render possible higher pressures in the absorber.

1. Absorber for converting solar rays into thermal energy, in particular for use in a solar collector, which is flowed through by a heat transport medium, characterized in that the absorber essentially comprises a non-porous, dark ceramic.

2. Absorber according to claim 1, characterized in that the non-porous ceramic is a non-oxide ceramic on the basis of silicon carbide.

3. Absorber according to claim 2, characterized in that the silicon carbide is present in technical form.

4. Absorber according to claim 3 characterized in that the absorber is embodied in a tubular manner.

5. Absorber according to claim 4, characterized in that the absorber comprises a plurality of tubular elements densely connected to one another.

6. Absorber according to claim 5, characterized in that the connection of two tubular elements is carried out by means of a slip joint.

7. Absorber according to claim 6, characterized in that metal clamps are used to secure a slip joint.

8. Absorber according to claim 6 characterized in that the seal of the slip joint is carried out by means of a silicon seal.

9. Absorber according to claim 6 characterized in that the seal of the slip joint is carried out by a refractory putty or adhesive.

10. (canceled)

11. (canceled)

12. Absorber according to claim 7 characterized in that the seal of the slip joint is carried out by means of a silicon seal.

13. Absorber according to claim 7 characterized in that the seal of the slip joint is carried out by a refractory putty or adhesive.

14. Absorber according to claim 1 characterized in that a mirror reflecting solar rays onto the absorber is provided.

15. Absorber according to claim 2 characterized in that a mirror reflecting solar rays onto the absorber is provided.

16. Absorber according to claim 3 characterized in that a mirror reflecting solar rays onto the absorber is provided.

17. Absorber according to claim 4 characterized in that a mirror reflecting solar rays onto the absorber is provided.

18. Absorber according to claim 5 characterized in that a mirror reflecting solar rays onto the absorber is provided.

19. Absorber according to claim 6 characterized in that a mirror reflecting solar rays onto the absorber is provided.

20. Absorber according to claim 7 characterized in that a mirror reflecting solar rays onto the absorber is provided.

21. Absorber according to claim 8 characterized in that a mirror reflecting solar rays onto the absorber is provided.

22. Absorber according to claim 9 characterized in that a mirror reflecting solar rays onto the absorber is provided.

23. Absorber according to claim 12 characterized in that a mirror reflecting solar rays onto the absorber is provided.

24. Absorber according to claim 13 characterized in that a mirror reflecting solar rays onto the absorber is provided.

25. Absorber according to claim 1 characterized in that the heat transport medium preferably comprises silicon oil.

26. Absorber according to claim 2 characterized in that the heat transport medium preferably comprises silicon oil.

27. Absorber according to claim 3 characterized in that the heat transport medium preferably comprises silicon oil.

28. Absorber according to claim 4 characterized in that the heat transport medium preferably comprises silicon oil.

29. Absorber according to claim 5 characterized in that the heat transport medium preferably comprises silicon oil.

30. Absorber according to claim 6 characterized in that the heat transport medium preferably comprises silicon oil.

31. Absorber according to claim 7 characterized in that the heat transport medium preferably comprises silicon oil.

32. Absorber according to claim 8 characterized in that the heat transport medium preferably comprises silicon oil.

33. Absorber according to claim 9 characterized in that the heat transport medium preferably comprises silicon oil.

34. Absorber according to claim 12 characterized in that the heat transport medium preferably comprises silicon oil.

35. Absorber according to claim 13 characterized in that the heat transport medium preferably comprises silicon oil.

36. Absorber according to claim 14 characterized in that the heat transport medium preferably comprises silicon oil.

37. Absorber according to claim 15 characterized in that the heat transport medium preferably comprises silicon oil.

38. Absorber according to claim 16 characterized in that the heat transport medium preferably comprises silicon oil.

39. Absorber according to claim 17 characterized in that the heat transport medium preferably comprises silicon oil.

40. Absorber according to claim 18 characterized in that the heat transport medium preferably comprises silicon oil.

41. Absorber according to claim 19 characterized in that the heat transport medium preferably comprises silicon oil.

42. Absorber according to claim 20 characterized in that the heat transport medium preferably comprises silicon oil.

43. Absorber according to claim 21 characterized in that the heat transport medium preferably comprises silicon oil.

44. Absorber according to claim 22 characterized in that the heat transport medium preferably comprises silicon oil.

45. Absorber according to claim 23 characterized in that the heat transport medium preferably comprises silicon oil.

46. Absorber according to claim 24 characterized in that the heat transport medium preferably comprises silicon oil.
